(19) United States
(12) Patent Application Publication
(10) Pub. No.: US 2018/0114780 A1
(43) Pub. Date: Apr. 26, 2018

(54) LIGHT EMITTING DEVICE ARRAY AND LIGHTING SYSTEM INCLUDING THE SAME

(71) Applicant: LG INNOTEK CO., LTD., Seoul (KR)

(72) Inventors: Jin Seok SUNG, Seoul (KR); Sung Jae KANG, Seoul (KR)

(73) Assignee: LG INNOTEK CO., LTD., Seoul (KR)

(21) Appl. No.: 15/559,354

(22) PCT Filed: Feb. 26, 2016
(86) PCT No.: PCT/KR2016/001927

§ 371 Date: Sep. 18, 2017

(30) Foreign Application Priority Data
Mar. 18, 2015 (KR) 10-2015-0037212

(51) Int. Cl. H01L 25/075; G02B 5/08; F21V 8/00; H01L 33/62; H01L 33/60; H01L 33/58

(52) U.S. Cl. CPC H01L 25/0753; G02B 5/0841; G02B 6/0031; G02B 6/0073; H01L 2933/0091; H01L 33/62; H01L 33/60; H01L 33/58; G02B 6/0068

(57) ABSTRACT

A light emitting device array according to an embodiment, comprises: a circuit board including a first electrode and a second electrode; a light emitting device disposed on the circuit board and including a first electrode pad and a second electrode pad electrically connected to the first electrode and the second electrode, respectively; and a reflector disposed around the light emitting device and including a plurality of sheets stacked.

### TECHNICAL FIELD

### Technical Field

Embodiments relates to a light emitting device array and light emitting the same, and more particularly to a light emitting device array can collect side light of a light emitting device by a reflector in which a plurality of sheets are stacked.

### Background Art

Generally, a light emitting device package includes a light emitting device such as a light emitting diode (LED) or a laser diode (LD), and a package body on which the light emitting device is mounted and on which an electrode is mounted. In the following description, a plurality of light emitting device packages for using as a display lamp or a display device in character or graphic images are defined as a light emitting device package array. Also, a process of forming a light emitting device package array by arranging and electrically connecting a plurality of light emitting device packages in a space is defined as a second level packaging process. The secondary level packaging process is, for example, a process of arranging a plurality of light emitting device packages on a printed circuit board and soldering the light emitting device package to a predetermined position by a reflow process.

The light emitting device package array can be formed freely by modularizing and arranging in a desired number and shape a single light emitting device package rather than manufacturing the light emitting device package array in one piece. However, when arranging the light emitting device package, the respective distances may be unevenly assembled, or the arrangement position may be changed due to thermal deformation in the second level packaging process.

In order to solve the above problems, a ‘light emitting device package and a light emitting device package array’ disclosed in Korean Patent No. 10-0735432 includes a light emitting device, a package body formed of a conductive material and formed with a cavity having a bottom surface on which the light emitting device is mounted and a side surface that reflects light emitted from the light emitting device, a first electrode protruding from the package body, and s second electrode inserted into the package body. And, a plurality of light emitting device packages are provided by fastening the first electrode and the second electrode, thereby improving alignment.

However, since the conventional ‘light emitting device package and light emitting device package array’ requires a process of fabricating the light emitting device package including a lead frame in order to arrange the light emitting devices at uniform intervals, therefore production cost increase and production time is increase.

### DISCLOSURE

### Technical Problem

Embodiments has been made in order to solve the above problems, and it is an object of the embodiments to provide a light emitting device array and a lighting system including the same, which can reduce manufacturing cost and time by simplifying a manufacturing process of the light emitting device array.

### Technical Solution

To achieve the above object, in one embodiment, a light emitting device array comprises a circuit board including a first electrode and a second electrode, a light emitting device disposed on the circuit board and including a first electrode pad and a second electrode pad electrically connected to the first electrode and the second electrode, respectively, and a reflector disposed around the light emitting device and including a plurality of sheets stacked.

An inner diameter of the reflector may decrease toward the circuit board.

An the inner diameter of the reflector may increase in a stepwise form from the circuit board.

An inner surface of the reflector toward the light emitting device may have a step, and an outer surface of the reflector may be flat.

A height of the reflector may be 1.1 to 1.3 times a height of the light emitting device.

The stacked sheet of the reflector may be made of a same material as the circuit board.

The reflector may include at least one of CEM(Composite Epoxy Materials)3 of FR4.

The inner surface of the reflector may have an inclination angle of 90 degrees to 150 degrees with respect to the circuit board.

The plurality of the sheets stacked in the reflector may be bonded by a bonding sheet.

In another embodiment, a light emitting device array comprises a circuit board including a first electrode and a second electrode, a light emitting device disposed on the circuit board and including a first electrode pad and a second electrode pad electrically connected to the first electrode and the second electrode, respectively, and a reflector disposed around the light emitting device and including a plurality of sheets having different thickness stacked.

An inner diameter of the reflector may decrease toward the circuit board.

A thickness of each of the plurality of sheets stacked may decrease toward an upper direction.

A thickness of each of the plurality of sheets stacked may increase toward an upper direction.

An outer surface of the reflector may be flat.

A height of the reflector may be 1.1 to 1.3 times a height of the light emitting device.

The reflector may include at least one of CEM(Composite Epoxy Materials)3 of FR4.

An inner surface of the reflector may have an inclination angle of 90 degrees to 150 degrees with respect to the circuit board.

The plurality of the sheets stacked in the reflector may be bonded with a bonding sheet.

In another embodiment, a light emitting system comprises the light emitting device array according to any one of claims 1 to 19, and an optical sheet configured to transmit light emitted from the light emitting device array.

### Advantageous Effects

According to the embodiment described above, the manufacturing process of the light emitting device array can be simplified, the production cost can be reduced, and the defect rate of the process can be reduced by omitting the step of manufacturing the lead frame of the light emitting device package.

Further, the light output characteristic can be improved according to the size of the light emitting device, and the angle of light emitted from the light emitting device can be improved.

### DESCRIPTION OF DRAWINGS

FIG. 1 is a perspective view showing a light emitting device array according to an embodiment.

FIG. 2A to 2F are cross-sectional views showing the first to sixth embodiments of the light-emitting device array.

FIG. 3 is a plan view showing a light emitting device array according to an embodiment.

FIG. 4 is a cross-sectional view illustrating an image display apparatus equipped with a light emitting device array according to an embodiment.

### BEST MODE

Reference will now be made in detail to preferred embodiments, examples of which are illustrated in the accompanying drawings.

It will be understood that when an element is referred to as being “on” or “under” another element, it can be directly on/under the element, or one or more intervening elements may also be present. In addition, when an element is referred to as being “on” or “under,” “under the element” as well as “on the element” may be included based on the element.

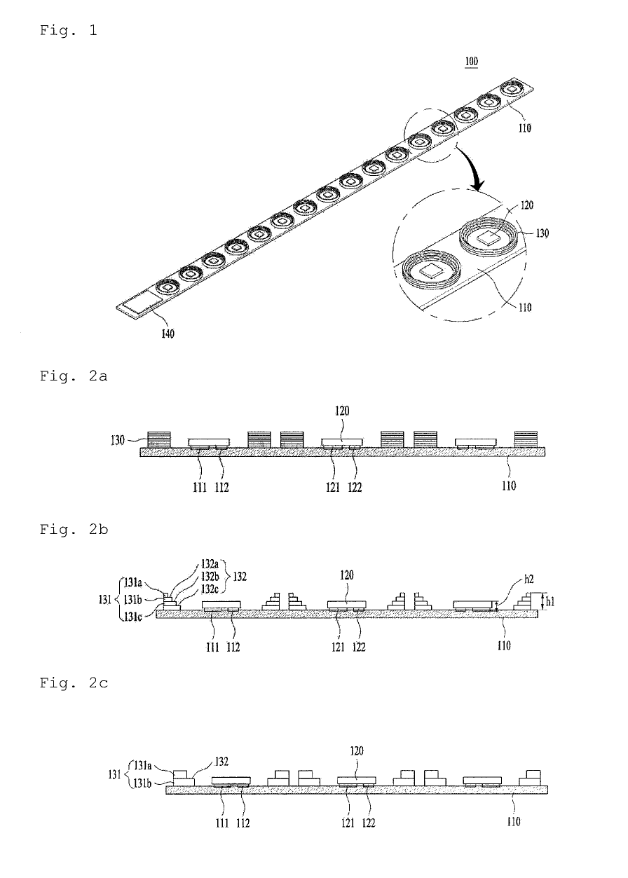

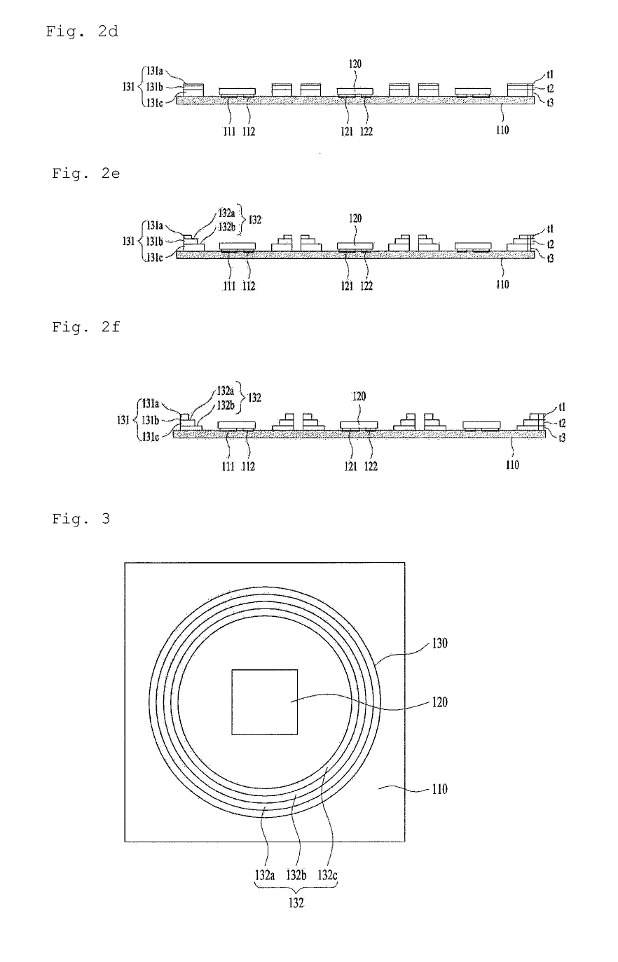

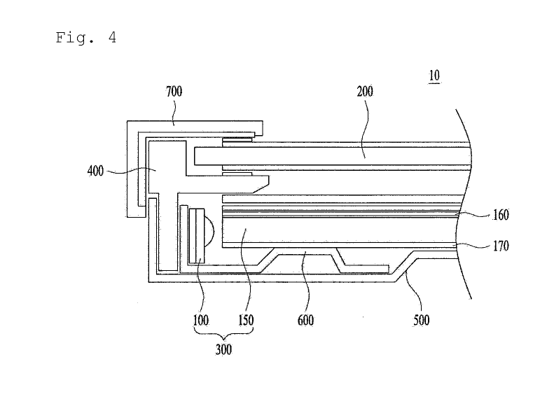

FIG. 1 is a perspective view showing a light emitting device array according to an embodiment, FIG. 2A to 2F are cross-sectional views showing the first to sixth embodiments of the light-emitting device array, and FIG. 3 is a plan view showing a light emitting device array according to an embodiment.

Referring to FIG. 1 to FIG. 3, the light emitting device array 100 according to the present embodiment includes a circuit board 110, a light emitting device 120 disposed on the circuit board 110, a reflector 130 disposed corresponding to a position where the light emitting device 120 is disposed and accommodates the light emitting device 120, a connector 140, and a power supply unit (not shown).

Here, the power supply unit (not shown) generates power consumed by the light emitting device 120 mounted on the light emitting device array 100, and the connector 140, which is disposed on one side of the light emitting device array 100, is connected with the power supply unit to supply power to the light emitting device array 100.

In the presented embodiment, the circuit board 110 may be a printed circuit board (PCB), a flexible printed circuit board (FPCB), or a metal core PCB (MCPCB). And, the printed circuit board is a single-sided PCB (Print Circuit Board), a double-sided PCB (Print Circuit Board), or a multiple-layer PCB (Print circuit Board).

In addition, the light emitting device 120 is disposed on the circuit board 110, a first electrode 111 and a second electrode 112 are provided on the circuit board 110, and the light emitting device 120 includes the first electrode pad 121 and the second electrode pad 122. And, the first electrode pad 121 and the second electrode pad 122 are electrically connected with the first electrode 111 and the second electrode 112 on the circuit board 110, respectively, to supply power to the light emitting device. The first electrode 111 and the second electrode 112 may be formed of a material such as aluminum, copper, gold, silver, nickel, titanium, or the like.

In the present embodiment, the light emitting device 120 may be a light emitting diode. The light emitting diode may be, for example, a colored light emitting diode that emits light such as red, green, blue, or white, or a UV (Ultra Violet) light emitting diode that emits ultraviolet light, without being limited thereto.

In addition, the plurality of light emitting devices 120 may include at least two or more light emitting devices 120 emitting different colors, which may be alternately mounted, may be mounted in groups according to the size of the light emitting devices, or the plurality of light emitting devices 120 emit single color are mounted, with being limited thereto.

For example, when the light emitting device array 100 emits white light, the plurality of light emitting devices 120 may include a light emitting device that emits red light and a light emitting device that emits blue light. Therefore, the light emitting devices emitting red light and blue light may be alternately mounted to form red light, blue light, and green light.

Meanwhile, the reflector 130 may be disposed on the circuit board 110 around the light emitting device 120 to receive the light emitting device 120.

In the present embodiment, the inner diameter of the reflector 130 may decrease toward the circuit board 110, and increases in a stepwise form from the circuit board 110.

The reflector 130 may have a plurality of sheets 131, 131a, 131b and 131c stacked thereon. An inner surface of the reflector 130 toward the light emitting device has a step, an outer surface of the reflector 130 is flat.

Here, a plurality of sheets 131, 131a, 131b and 131c may be stacked so that the inner surface of the reflector 130 has an inclination angle of 90° to 150° with respect to the circuit board 110. And, the reflector 130 may control the light distribution method differently according to the purpose of using light emitted from the light emitting device.

In order for light distribution have a straight, as shown in FIG. 2a, the sheets 131, 131a, 131b and 113c of the reflector 130 having the same size may be vertically stacked to the inner wall of the reflector 130 facing the light emitting device 120 have a flat surface and do not have a step in the first embodiment.

In addition, the sheets 131, 131a, 131b and 131c of the reflector 130 may be stacked on the circuit board 110 in a stepwise manner so that areas of the sheets 131, 131a, 131b and 131c may become narrower toward the direction in which the light emitting device 120 is disposed. In order to provide a light distribution characteristic in which light emitted from the light emitting device is diffused, as shown in FIG. 2B and FIG. 2C, the sheets 120a, 130a, 131b, and 131c having different size in the plurality of the reflector 130 have inner surfaces 131, 132a, 132b, and 132c facing with the light emitting device 120, respectively, having stepwise form.

And, a number of the sheets 131, 131a, 131b and 131c stacked may vary depending on thicknesses of the sheets 131, 131a, 131b and 131c of the reflector 130. Since the height of the reflector 130 can be determined by the thicknesses of the sheets 131, 131a, 131b and 131c and the number of the sheets 131, 131a, 131b and 131c, the height of the reflector 130 may be determined according to the size of the light emitting device disposed in the light emitting device array.

As shown in FIG. 2d, the sheets 131a, 131b, and 131c of the reflector 130 having the same size are vertically stacked to the inner surface of the reflector 130 facing the light emitting device 120 have a flat surface and do not have a step in the fourth embodiment. Here, thicknesses t1, t2 and t3 of the sheets 131a, 131b and 131c may be different from each other.

In the fourth embodiment, t3 may be larger than t2, t2 may be larger than t1, and the light emitting device and the reflector may be disposed on the board in accordance with the ratio of the height of the reflector to the height of the light emitting device for high light output. And, the sheets 131a, 131b, and 131c having different thicknesses may be stacked so that the height of the reflector may be adjusted according to the height of the light emitting device 120, thin sheets are stacked toward un upper direction to adjust slightly the height of the reflector.

Referring to FIG. 2e and FIG. 2f, in the fifth embodiment and the sixth embodiment, the inner diameter of the reflector becomes smaller toward the circuit board, and the sheets 131a, 131b and 131c stacked may have different thicknesses.

As shown in FIG. 2e, t3 may be greater than t2 and t2 may be greater than t1 so that the thickness of the plurality of sheets 131a, 131b, and 131c stacked becomes thinner toward the upper direction, and as shown in FIG. 2f, t1 may be greater than t2 and t2 may be greater than t3 so that the thickness of the plurality of sheets 131a, 131b, and 131c stacked becomes thicker toward the upper direction

As described above, in the structure in which a plurality of sheets are stacked, the height of the reflector may be adjusted according to the height of the light emitting device 120. And, the plurality of sheets 131, 131a, 131b, and 131c may be stacked so that the inner surface of the reflector, that is, the inner surfaces of the stacked sheets has an inclination angle of 90° to 150° with respect to the circuit board 110.

Therefore, according to this embodiment, when the light emitting device which can be electrically connected to the first electrode and the second electrode on the circuit board of the light emitting device array is disposed on the circuit board, since the structure of the reflector may be changed by stacking the sheets regardless of the size of the light emitting device, therefore the light distribution method of the light emitting device can be easily controlled.

In addition, the height h1 of the reflector may be 1.1 to 1.3 times greater than the height h2 of the light emitting device disposed on the circuit board 110, because the light output increases as the height of the reflector 130 decreases. However, the height of the reflector can be determined in consideration of both the light distribution characteristic and the light output, thus the present embodiment is not limited thereto.

Meanwhile, the seat 131 of the reflector 130 may be made of the same material as the circuit board 110, and the material of the reflector may include at least one of CEM (Composite Epoxy Materials)3 and FR4.

And, the sheets 131, 131a, 131b, and 131c of reflector 130 may be bonded with a bonding sheet, which is an adhesive tape, between the respective layers of the sheet to bond individual layers of the sheet.

FIG. 4 is a cross-sectional view illustrating an image display apparatus equipped with a light emitting device array according to an embodiment.

Referring to FIG. 4, an image display apparatus 10 having a light emitting device array according to the embodiment includes a liquid crystal 200, a backlight unit 300, a mold frame 400, a bottom chassis 500, a heat-radiating block 600, and a top case 700.

The liquid crystal 200 may display an image by using a light source emitted from the backlight unit 300. And, in addition to the liquid crystal 200, other types of display devices requiring a light source may be provided.

The liquid crystal 200 is arranged between glass bodies and a polarization plate is mounted on the glass bodies in order to use a polarization property of light. Here, the liquid crystal 200, which has physical properties between liquids and solids, has a structure in which liquid crystal molecules with fluidity are aligned regularly as crystals. In this regard, an image is displayed using a property in which molecular arrangement of the liquid crystal molecules are changed by an external electric field.

The liquid crystal 200 used in the image display apparatus 10 may be of an active matrix type, and uses a transistor as a switch for adjusting a voltage applied to each pixel.

The liquid crystal 200 may include a color filter substrate (not shown) and a thin film transistor substrate (not shown) facing each other with a liquid crystal therebetween, and the color filter substrate may realize the color of the image displayed by the liquid crystal 200. The color filter substrate may receive light projected from the liquid crystal 200 and transmit only red, green and blue light for each pixel to display the image. And, the thin film transistor substrate may apply a driving voltage provided from the printed circuit board to the liquid crystal in response to a driving signal provided from the printed circuit board.

In addition, the backlight unit 300 includes a light emitting device array 100 emit light and a light guide plate 150 that changes light emitted from the light emitting device array 100 into a planar light source to provide the liquid crystal 200, an optical sheet 160 improves an uniformity of the luminance distribution of light provided from the light guide plate 150 and the reflective sheet 170 reflects light emitted to a back of the light guide plate 150 to the light guide plate 150.

The optical sheet 160 is formed of a polymer material that is light-transmitting and elastic, and the polymer may have a prism layer in which a plurality of steric structures are repeatedly formed.

The light guide plate 150 scatters light emitted from the light emitting device package module and thus enables the emitted light to be uniformly dispersed over the entire region of a screen of the display device. Thus, the light guide plate 150 is formed of a material having a high refractive index and transmittance. For example, the light guide plate 150 may be formed of polymethylmethacrylate (PMMA), polycarbonate (PC), polyethylene (PE), or the like. In addition, when the light guide plate 150 is not formed, an air-guide type display device may be constructed.

The reflective sheet 170 can be made of a material having a high reflectivity and can be used in an ultra-thin shape, and a polyethylene terephthalate (PET) can be used.

The light emitting device array 100 may include the plurality of the light emitting device and a circuit board on which the reflectors that accommodates the light emitting devices are disposed, and a circuit board such as a PCB may be used.

The backlight unit 300 includes a diffusion film (not shown) for diffusing light incident from the light guide plate 150 toward the liquid crystal 200, a prism film (not shown) for enhancing vertical incidence by condensing the diffused light, and a protective film for protecting the prism film.

The mold frame 400 may be connected to the light emitting device array 100, the liquid crystal 200, and the light guide plate 150 so as to fix the components mounted in the image display device 10.

The lower chassis 500 may be provided to receive the mold frame 400, the light emitting device array 100, and the light guide plate 150, and an entire surface of the lower chassis 500 may be coated with a highly reflective material.

In addition, a heat dissipation block 600 is disposed on an inner surface of the lower chassis 500 and a light emitting device array 100 is mounted on one side of the heat dissipation block 600 so as to dissipate heat transferred from the light emitting device arranged in the light emitting device array 100.

The top case 700 is disposed above the molding frame 400 to support the components mounted in the image display device 10 so as to prevent the components from moving and to fix the molding frame 400 and the lower chassis 500.

The above-described light emitting device array may be used in an illumination device in addition to the image display device, and the image display device and the illumination device may be collectively referred to as an illumination system.

Conventionally, a large amount of cost has been incurred in manufacturing the lead frame in the structure of the light emitting device package, resulting in low productivity and time-consuming production. However, in this embodiments, a lead frame is omitted, and a reflector provided with a light emitting device and a plurality of sheets stacked in the light emitting device array is disposed to focus light emitted from side surface of the light emitting device or improve the light output characteristic according to the size of the light emitting device.

Further, by omitting the step of manufacturing the lead frame which requires a lot of manufacturing cost, the production process of the light emitting device array can be simplified, the production cost can be reduced, and the defect rate of the process can be reduced.

Although embodiments have been described with reference to a number of illustrative embodiments thereof, it should be understood that the embodiments are illustrative and not restrictive and that numerous other modifications and applications may be devised by those skilled in the art that will fall within the intrinsic aspects of the embodiments. For example, various variations and modifications are possible in concrete constituent elements of the embodiments. In addition, it is to be understood that differences relevant to the variations and modifications fall within the spirit and scope of the present disclosure defined in the appended claims.

### MODE FOR INVENTION

The mode for carrying out the invention has been fully described above in the “Best Mode”.

### INDUSTRIAL APPLICABILITY

The light emitting device array according to the present embodiment can improve the angle and the light output characteristic of the light emitted from the light emitting device, and can be mounted on an image display device or an illumination system.

1. A light emitting device array comprising:
a circuit board including a first electrode and a second electrode;
a light emitting device disposed on the circuit board and including a first electrode pad and a second electrode pad electrically connected to the first electrode and the second electrode, respectively; and
a reflector disposed around the light emitting device and including a plurality of sheets stacked,
wherein an inner surface of the reflector disposed in a first direction facing adjacent light emitting device has a step, and
wherein an outer surface of the reflector disposed in a second direction opposite to the first direction is flat.

2. The light emitting device array according to claim 1, wherein an inner diameter of the reflector decreases toward the circuit board.

3. The light emitting device array according to claim 2, wherein the inner diameter of the reflector increases in a stepwise form from the circuit board.

4.-5. (canceled)

6. The light emitting device array according to claim 1, wherein a height of the reflector is 1.1 to 1.3 times a height of the light emitting device.

7. The light emitting device array according to claim 1, wherein the sheet of the reflector is made of a same material as the circuit board.

8. The light emitting device array according to claim 1, wherein the reflector includes at least one of CEM(Composite Epoxy Materials)3 of FR4.

9. The light emitting device array according to claim 1, wherein an inner surface of the reflector has an inclination angle of 90 degrees to 150 degrees with respect to the circuit board.

10. The light emitting device array according to claim 1, wherein the plurality of the sheets stacked in the reflector are bonded by a bonding sheet.

11. A light emitting device array comprising:
a circuit board including a first electrode and a second electrode;
a light emitting device disposed on the circuit board and including a first electrode pad and a second electrode pad electrically connected to the first electrode and the second electrode, respectively; and
a reflector disposed around the light emitting device and including a plurality of sheets having different thickness stacked,
wherein an inner surface of the reflector disposed in a first direction facing adjacent light emitting device has a step, and
wherein an outer surface of the reflector disposed in a second direction opposite to the first direction is flat.

12. The light emitting device array according to claim 11, wherein an inner diameter of the reflector decreases toward the circuit board.

13. The light emitting device array according to claim 11, wherein a thickness of each of the plurality of sheets stacked decreases toward an upper direction.

14.-15. (canceled)

16. The light emitting device array according to claim 11, wherein a height of the reflector is 1.1 to 1.3 times a height of the light emitting device.

17. The light emitting device array according to claim 11, wherein the reflector includes at least one of CEM(Composite Epoxy Materials)3 of FR4.

18. The light emitting device array according to claim 11, wherein an inner surface of the reflector has an inclination angle of 90 degrees to 150 degrees with respect to the circuit board.

19. The light emitting device array according to claim 11, wherein the plurality of the sheets stacked in the reflector are bonded with a bonding sheet.

20. A light emitting system comprising;
a light emitting device array comprising a circuit board including a first electrode and a second electrode, a light emitting device disposed on the circuit board and including a first electrode pad and a second electrode pad electrically connected to the first electrode and the second electrode, respectively, and a reflector disposed around the light emitting device and including a plurality of sheets stacked, wherein an inner surface of the reflector disposed in a first direction facing adjacent light emitting device has a step, and wherein an outer surface of the reflector disposed in a second direction opposite to the first direction is flat; and
an optical sheet configured to transmit light emitted from the light emitting device array.

21. The light emitting system according to claim 20, wherein an inner diameter of the reflector decreases toward the circuit board.

22. The light emitting system according to claim 20, wherein the inner diameter of the reflector increases in a stepwise form from the circuit board.

23. The light emitting system according to claim 20, wherein a thickness of each of the plurality of sheets stacked decreases toward an upper direction.

24. The light emitting system according to claim 20, wherein an inner surface of the reflector has an inclination angle of 90 degrees to 150 degrees with respect to the circuit board.
